(19) United States
(12) Patent Application Publication
(10) Pub. No.: US 2012/0119345 A1
(43) Pub. Date: May 17, 2012

(54) INTEGRATED CIRCUIT PACKAGING SYSTEM WITH DEVICE MOUNT AND METHOD OF MANUFACTURE THEREOF

(76) Inventors: SungWon Cho, Icheon-si (KR); DaeSik Choi, Seoul (KR); HyungSang Park, Hanam-si (KR)

(21) Appl. No.: 12/946,841

(22) Filed: Nov. 15, 2010

(51) Int. Cl. H01L 23/538; H01L 21/50

(52) U.S. Cl. 257/690; 438/124; 257/E23.169; 257/E21.499

(57) ABSTRACT

A method of manufacture of an integrated circuit packaging system includes: providing a base substrate having a base bottom side and a base top side; mounting an integrated circuit perpendicular to the base top side, the integrated circuit having a first conductor partially exposed at a first end facing and connected to the base top side; and forming an encapsulation over the integrated circuit.

### TECHNICAL FIELD

The present invention relates generally to an integrated circuit packaging system, and more particularly to a system for a device mount.

### BACKGROUND ART

Semiconductor chips have become progressively more complex, driven in large part by the need for smaller chip sizes. Such need is for compact or portable electronic devices, such as cell phones, smart phones, personal media systems, and ultraportable computers.

There are a number of conventional processes for packaging integrated circuit (IC) dice. By way of example, many IC packages utilize a metallic leadframe that has been stamped or etched from a metal sheet to provide electrical interconnects to external devices. The die may be electrically connected to the leadframe by means of bonding wires, solder bumps or other suitable electrical connections.

In response to the smaller chip size, packaging technologies have evolved, for example, to enable an increased lead density, which can reduce the footprint area of a package mounted on a printed circuit board (PCB). Some packaging technologies may enable this increased lead density by providing rows of leads connected to a disposable portion of a leadframe.

However, manufacturing processes for such leadframes may not be scalable. As lead density requirements further increase, it may be desirable to use packaging technologies that are more scalable in terms of lead density.

Moreover, it may be desirable to further reduce package size in additional ways. At the same time, it may be desirable to maintain sufficient structural integrity and to facilitate surface mounting of the package to a PCB. It may also be desirable to formulate a packaging process designed to meet these objectives. Current packaging solutions can meet some of these objectives but may not be able to meet most, or all, of these objectives.

Thus, a need still remains for increased density and structural integrity. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: providing a base substrate having a base bottom side and a base top side; mounting an integrated circuit perpendicular to the base top side, the integrated circuit having a first conductor partially exposed at a first end facing and connected to the base top side; and forming an encapsulation over the integrated circuit.

The present invention provides an integrated circuit packaging system, including: a base substrate having a base bottom side and a base top side; an integrated circuit perpendicular to the base top side, the integrated circuit having a first conductor partially exposed at a first end facing and connected to the base top side; and an encapsulation over the integrated circuit.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit packaging system taken along line 1-1 of FIG. 2 in a first embodiment of the present invention.

FIG. 2 is a top view of the integrated circuit packaging system.

FIG. 3 is a cross-sectional view of the integrated circuit taken along line 3-3 of FIG. 4.

FIG. 4 is a top view of the integrated circuit.

FIG. 5 is a cross-sectional view of the integrated circuit packaging system taken along line 5-5 of FIG. 6 in a wafer providing phase of manufacture.

FIG. 6 is a top view of the integrated circuit packaging system in the wafer providing phase.

FIG. 7 is the structure of FIG. 5 taken along line 7-7 of FIG. 8 in a conductor forming phase.

FIG. 8 is a top view of the integrated circuit packaging system in the conductor forming phase.

FIG. 9 is the structure of FIG. 7 taken along line 9-9 of FIG. 10 in a singulation phase.

FIG. 10 is a top view of the integrated circuit packaging system in the singulation phase.

FIG. 11 is the structure of FIG. 9 taken along line 11-11 of FIG. 12 in a removal phase.

FIG. 12 is a top view of the integrated circuit packaging system in the removal phase.

FIG. 13 is the structure of FIG. 11 in a mounting phase.

FIG. 14 is the structure of FIG. 13 taken along line 14-14 of FIG. 15 in a molding phase.

FIG. 15 is a top view of the integrated circuit packaging system in the molding phase.

FIG. 16 is the structure of FIG. 14 in an attaching phase.

FIG. 17 is a cross-sectional view of an integrated circuit packaging system in a second embodiment of the present invention.

FIG. 18 is a cross-sectional view of the integrated circuit taken along line 18-18 of FIG. 19.

FIG. 19 is a top view of the integrated circuit.

FIG. 20 is a cross-sectional view of the integrated circuit packaging system in a substrate providing phase of manufacture.

FIG. 21 is the structure of FIG. 20 in a first deposition phase.

FIG. 22 is the structure of FIG. 21 in a device mounting phase.

FIG. 23 is the structure of FIG. 22 in a second deposition phase.

FIG. 24 is the structure of FIG. 23 in a substrate attaching phase.

FIG. 25 is the structure of FIG. 24 in a molding phase.

FIG. 26 is the structure of FIG. 25 in a connector attaching phase.

FIG. 27 is a flow chart of a method of manufacture of the integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGS. Similarly, although the views in the drawings for ease of description generally show similar orientations, this depiction in the FIGS. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” means that there is direct contact between elements. The term “directly on” means that there is direct contact between one element and another element without an intervening element.

The term “active side” refers to a side of a die, a module, a package, or an electronic structure having active circuitry fabricated thereon or having elements for connection to the active circuitry within the die, the module, the package, or the electronic structure. The term “processing” as used herein includes deposition of material or photoresist, patterning, exposure, development, etching, cleaning, and/or removal of the material or photoresist as required in forming a described structure.

A method for increasing circuit density in an assembly step can include many methods, such as a package stack, chip stack, or module. Chip stack in DRAM modules can be a method for increasing circuit density. However, when many chips are stacked in conventional chip stacks, problems can occur.

The problems can include load, chip crack, overhang, and handing. Further, the problems can include misalignment or tilt of a chip by one-sided force due to solder bump existing on one side of the chip. Yet further, the problems can include increase of mounting area or package size.

For example, the problems can occur with more than 10 chips stacked. Also for example, the problems can occur between a chip and another chip. Embodiments of the present invention provide answers or solutions to the problems by providing a structure having a chip vertically stacked with a through hole at a sidewall of the chip.

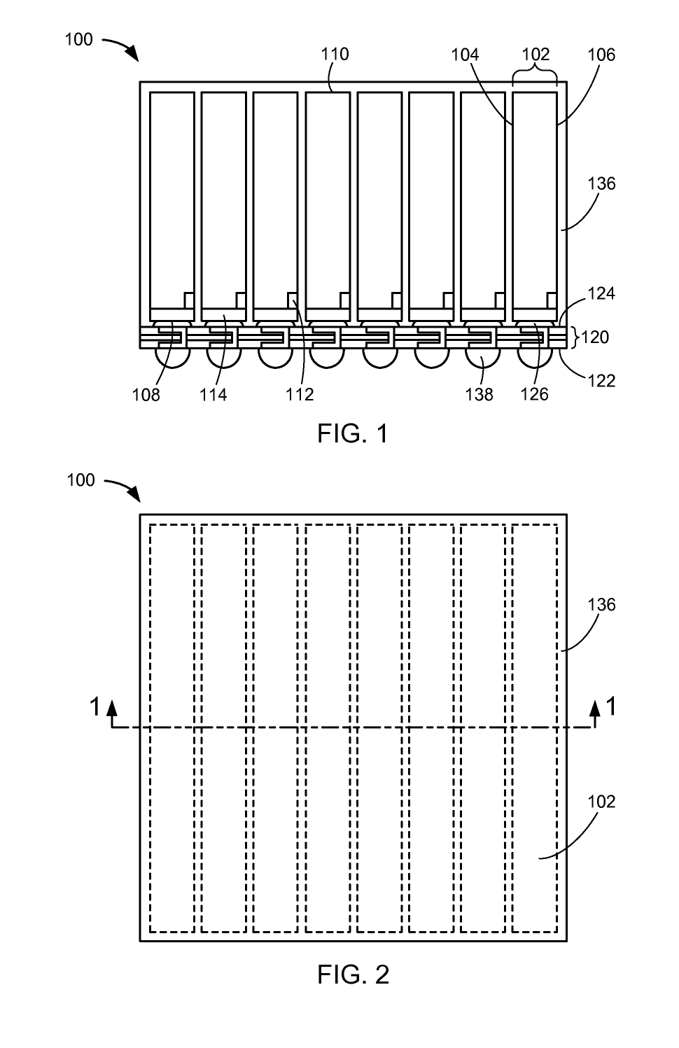

Referring now to FIG. 1, therein is shown a cross-sectional view of an integrated circuit packaging system 100 taken along line 1-1 of FIG. 2 in a first embodiment of the present invention. The integrated circuit packaging system 100 can include a structure having a chip vertically stacked with a through hole at a sidewall of the chip.

The integrated circuit packaging system 100 can include a stack of a number of chips, having sidewalls with through holes, mounted on a substrate without chip damage, such as chip crack or stress, as well as without further film and wire bonding. The chip can be stacked at wafer level in mass production.

The integrated circuit packaging system 100 can include an integrated circuit 102, which is a semiconductor device. For example, the integrated circuit 102 can include the chip or an integrated circuit die.

The integrated circuit 102 can include an inactive side 104 and an active side 106 opposite the inactive side 104. The integrated circuit 102 can include a first end 108 and a second end 110 opposite the first end 108. The first end 108 and the second end 110 are planar surfaces of an extent of a perimeter of sidewalls of the integrated circuit 102.

A plane of a portion of the first end 108 can intersect planes of portions of the inactive side 104 and the active side 106. At least a portion of the first end 108 can be perpendicular to the inactive side 104 or the active side 106.

A plane of a portion of the second end 110 can intersect planes of portions of the inactive side 104 and the active side 106. At least a portion of the second end 110 can be perpendicular to the inactive side 104 or the active side 106.

The integrated circuit 102 can include a first terminal 112, which provides electrical connectivity from or to the integrated circuit 102. For example, the first terminal 112 can include a bond pad. The first terminal 112 can be formed at the active side 106.

The integrated circuit 102 can include a first conductor 114, which is electrically connected to the first terminal 112. For example, the first conductor 114 can be formed with an electrically conductive element.

The first conductor 114 can be formed through the integrated circuit 102. The first conductor 114 can be formed at the first end 108. The first conductor 114 can be directly on a portion of the first terminal 112.

A plane of a portion of a side of the first conductor 114 can be coplanar with a plane of a portion of the inactive side 104. A plane of a portion of a side of the first conductor 114 can be coplanar with a plane of a portion of the active side 106.

The integrated circuit packaging system 100 can include a base substrate 120, which is a support structure formed to mount a semiconductor device thereon and electrically connect the semiconductor device thereto. The base substrate 120 can include a base bottom side 122 and a base top side 124 opposite the base bottom side 122. The base substrate 120 can include a number of pads, vertical insertion areas (vias), conductive layers, traces, or a combination thereof to provide electrical connectivity between the base bottom side 122 and the base top side 124.

The integrated circuit 102 can include the first end 108 facing the base top side 124. The integrated circuit 102 can include the second end 110 facing away from the base top side 124. The integrated circuit 102 can be mounted over or on the base top side 124.

The integrated circuit 102 can include a portion of the inactive side 104 or a portion of the active side 106 perpendicular to the base top side 124. The integrated circuit 102 can include a portion of the first end 108 parallel to the base top side 124.

The integrated circuit packaging system 100 can include a first connector 126, which is electrically conductive. The first connector 126 can be electrically connected to the first conductor 114 and the base top side 124 providing high-speed reply as a flip chip.

The integrated circuit packaging system 100 can include a number of the integrated circuit 102 laterally adjacent one another and mounted over the base top side 124. In other words, the term “laterally adjacent” means that the integrated circuit 102 and another of the integrated circuit 102 are mounted on the base top side 124 without being stacked over one another. The integrated circuit packaging system 100 can include a number of the first connector 126 connected to a number of the integrated circuit 102 and the base top side 124.

The integrated circuit packaging system 100 can include an encapsulation 136, which covers a semiconductor package to seal a semiconductor device providing mechanical and environmental protection. The encapsulation 136 can be formed over the base top side 124, the integrated circuit 102, and the first connector 126.

The integrated circuit packaging system 100 can include an external connector 138, which is an electrical connector that provides electrical connectivity between the base substrate 120 and an external system (not shown). The integrated circuit packaging system 100 can include a number of the external connector 138 connected to the base bottom side 122.

It has been discovered that the first conductor 114 covers and protects the integrated circuit 102 at the first end 108 from the mounting force when mounting the integrated circuit 102 to the base substrate 120 thereby eliminating chip damages.

It has also been discovered that the first connector 126 connected to the first conductor 114 significantly reduces misalignment or tilt of the integrated circuit 102 without further film attachment or wire bonding processes. Further to the discovery, the first connector 126 electrically connected to the first conductor 114 provides high-speed reply thereby significantly improving electrical performance.

Referring now to FIG. 2, therein is shown a top view of the integrated circuit packaging system 100. The integrated circuit packaging system 100 can include a number of the integrated circuit 102, shown as dash rectangles. The integrated circuit packaging system 100 can include the encapsulation 136 covering a number of the integrated circuit 102.

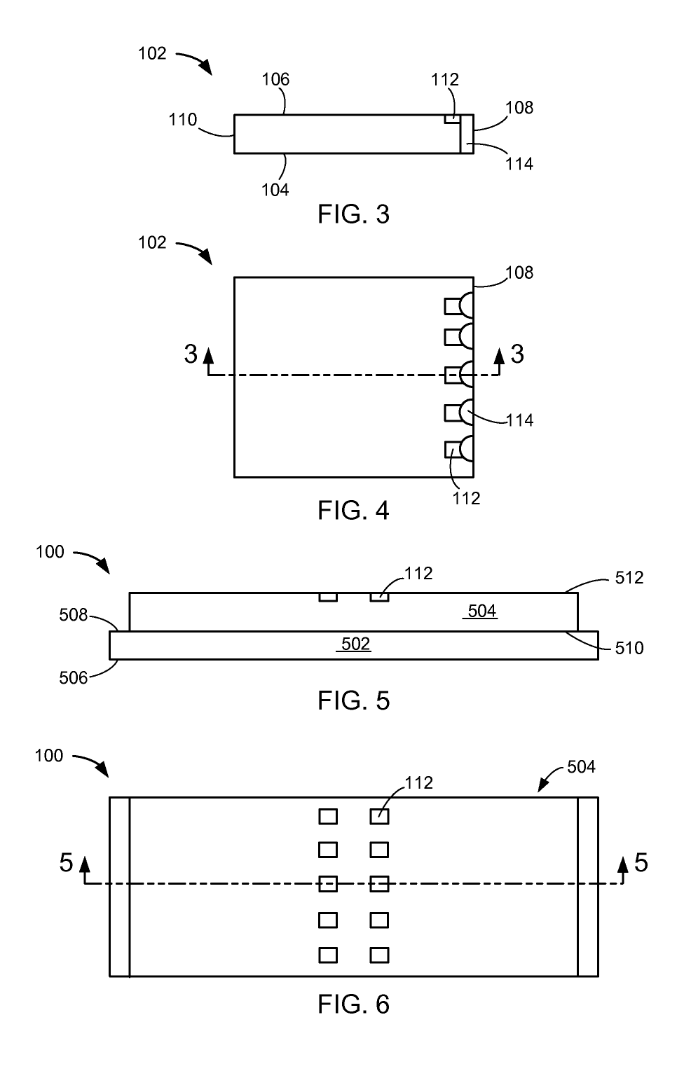

Referring now to FIG. 3, therein is shown a cross-sectional view of the integrated circuit 102 taken along line 3-3 of FIG. 4. The integrated circuit 102 can include the inactive side 104, the active side 106, the first end 108, and the second end 110. The integrated circuit 102 can include the first terminal 112 at the active side 106.

The integrated circuit 102 can include the first conductor 114 at the first end 108 and electrically connected to the first terminal 112. The integrated circuit 102 can include the first conductor 114 perpendicular to the first terminal 112.

Referring now to FIG. 4, therein is shown a top view of the integrated circuit 102. The integrated circuit 102 can include a number of the first terminal 112 and a number of the first conductor 114 connected thereto. The integrated circuit 102 can include a number of the first terminal 112 and a number of the first conductor 114 formed in a row or an array adjacent or at the first end 108.

Referring now to FIG. 5, therein is shown a cross-sectional view of the integrated circuit packaging system 100 taken along line 5-5 of FIG. 6 in a wafer providing phase of manufacture. The integrated circuit packaging system 100 can include a carrier 502, which is a support structure provided to mount a wafer 504 thereon. The carrier 502 can include a carrier bottom side 506 and a carrier top side 508 opposite the carrier bottom side 506.

The wafer 504 includes a structure formed with a semiconductor material used in fabrication of integrated circuits. For example, the semiconductor material can include silicon.

The wafer 504 can include a wafer bottom side 510 and a wafer top side 512 opposite the wafer bottom side 510. The wafer 504 can be mounted with the wafer bottom side 510 on the carrier top side 508. The wafer 504 can include the first terminal 112 formed at the wafer top side 512.

Referring now to FIG. 6, therein is shown a top view of the integrated circuit packaging system 100 in the wafer providing phase. The integrated circuit packaging system 100 can include the wafer 504 having a number of the first terminal 112. A number of the first terminal 112 can be formed in a row or an array.

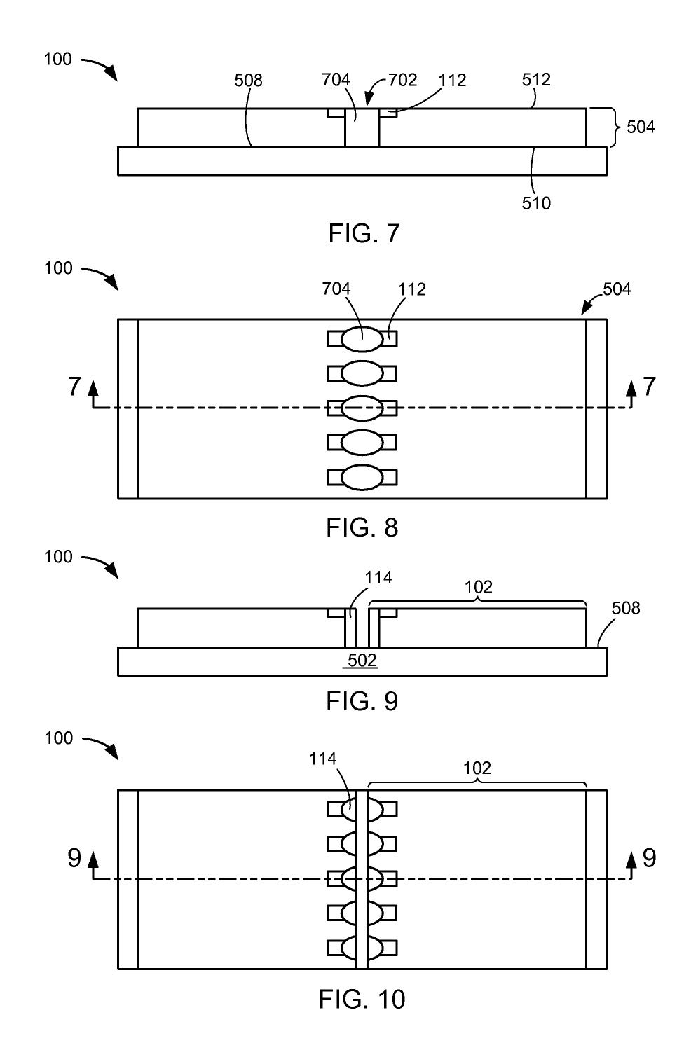

Referring now to FIG. 7, therein is shown the structure of FIG. 5 taken along line 7-7 of FIG. 8 in a conductor forming phase. The conductor forming phase can include a removal process that removes a portion of the wafer 504 forming a hole 702 through the wafer 504. The hole 702 can extend between the wafer bottom side 510 and the wafer top side 512.

For example, the hole 702 can be a through hole of a chip sidewall. Also for example, the removal process can include laser, drilling, or any other removal methods.

The conductor forming phase can include a filling process that fills the hole 702 with an electrically conductive material or an electrically conductive element forming a conductive layer 704. For example, the filling process can include plating or any other filling methods.

The conductive layer 704 can be electrically connected to the first terminal 112. The conductive layer 704 can be formed within the hole 702 and directly on a portion of the carrier top side 508. The conductive layer 704 can be formed through the wafer 504.

Referring now to FIG. 8, therein is shown a top view of the integrated circuit packaging system 100 in the conductor forming phase. The wafer 504 can include a number of the conductive layer 704 electrically connected to a number of the first terminal 112.

A number of the conductive layer 704 can be formed in a row or an array. For illustrative purposes, the conductive layer 704 is shown with an oval, although it is understood that the conductive layer 704 can be formed with any shapes. For example, the conductive layer 704 can be formed in a geometric shape of a circle or a rectangle.

Referring now to FIG. 9, therein is shown the structure of FIG. 7 taken along line 9-9 of FIG. 10 in a singulation phase. The wafer 504 of FIG. 7 can be singulated producing individual units of the integrated circuit 102.

The wafer 504 can be singulated through the conductive layer 704 of FIG. 7 forming the first conductor 114. The wafer 504 can be singulated with a portion of the conductive layer 704 removed exposing a portion of the carrier top side 508 of the carrier 502.

The singulation process can include a singulation process including a mechanical or optical process. For example, the singulation process can include sawing.

Referring now to FIG. 10, therein is shown a top view of the integrated circuit packaging system 100 in the singulation phase. The wafer 504 of FIG. 7 can be singulated to produce individual units of the integrated circuit 102 having a number of the first conductor 114 formed in a row or an array.

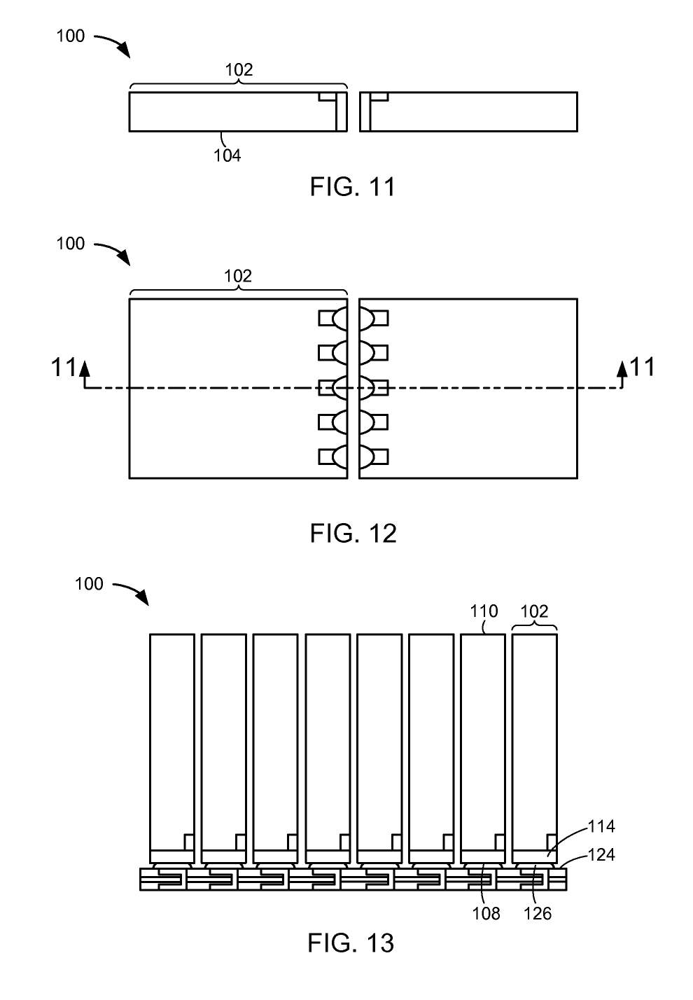

Referring now to FIG. 11, therein is shown the structure of FIG. 9 taken along line 11-11 of FIG. 12 in a removal phase. The carrier 502 of FIG. 9 can be removed exposing the inactive side 104 of the integrated circuit 102.

The inactive side 104 can include characteristics of the carrier 502 removed. The characteristics of the carrier 502 removed can include the inactive side 104 having etched marks, grinding marks, sanding marks, other removal marks, or chemical residue.

Referring now to FIG. 12, therein is shown a top view of the integrated circuit packaging system 100 in the removal phase. The top view depicts the integrated circuit 102 with the carrier 502 of FIG. 10 removed.

Referring now to FIG. 13, therein is shown the structure of FIG. 11 in a mounting phase. The integrated circuit 102 can be mounted over or on the base top side 124. The integrated circuit 102 can include the first end 108 facing the base top side 124.

The integrated circuit packaging system 100 can include a number of the integrated circuit 102 adjacent one another and mounted over the base top side 124. The integrated circuit packaging system 100 can include a number of the first connector 126 connected to a number of the first conductor 114 and the base top side 124. The first connector 126 can be directly on the first conductor 114 and the base top side 124.

For example, the first connector 126 can include a conductive ball, a conductive bump, or a conductive paste. Also for example, the first connector 126 can be formed with a conductive material including solder, a metal, or a metallic alloy.

The integrated circuit 102 can include any heights or shapes based on various circuit designs. The height is defined as a distance between the first end 108 and the second end 110.

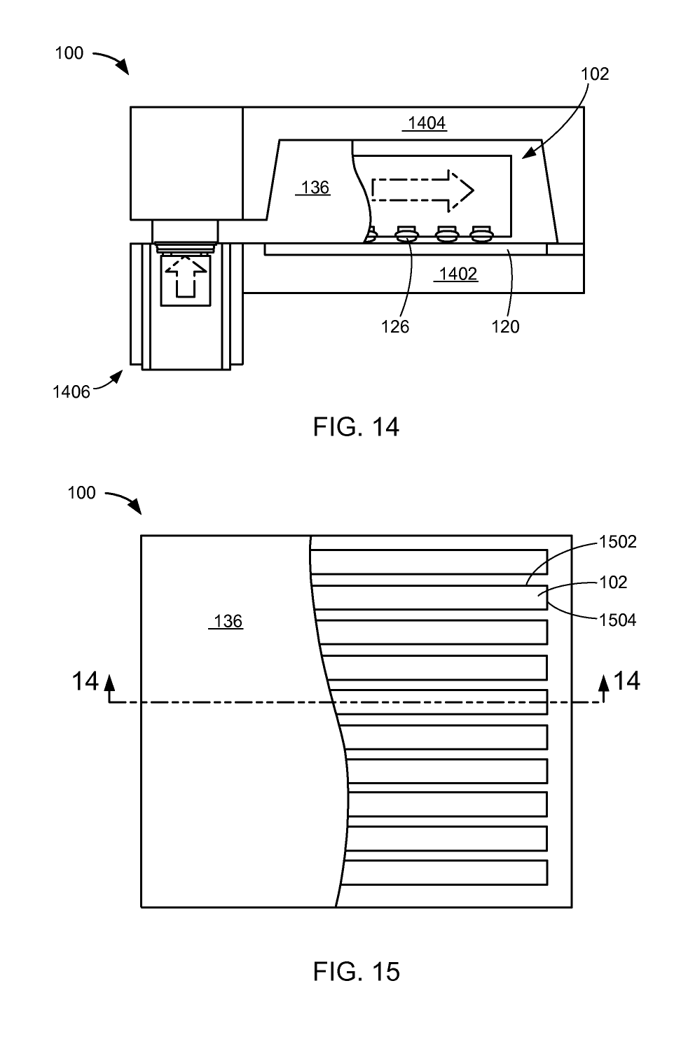

Referring now to FIG. 14, therein is shown the structure of FIG. 13 taken along line 14-14 of FIG. 15 in a molding phase. For example, the molding phase can include a molding process including transfer molding, injection molding, or any other molding processes.

The integrated circuit packaging system 100 can include a bottom chase 1402 and a top chase 1404. The bottom chase 1402 can be under or directly on the base substrate 120. The top chase 1404 can be over the integrated circuit 102.

The integrated circuit packaging system 100 can include a molding equipment 1406, which is a machine or device that encapsulates integrated circuits. The molding equipment 1406 can transfer an encapsulant or a mold material to form the encapsulation 136, as shown with arrows indicating a molding process flow.

The encapsulation 136 can be formed over the base substrate 120. The encapsulation 136 can cover the integrated circuit 102 and the first connector 126.

Die tilt or displacement can be eliminated with the integrated circuit 102 having a volume larger than a volume of a number of the first connector 126. Die tilt or displacement can be further eliminated with the integrated circuit 102 attached to the base substrate 120 with the first connector 126. Elimination of die tilt or displacement can prevent deflection or movement of the integrated circuit 102.

For illustrative purposes, the encapsulation 136 is shown in the process of being formed. Also for illustrative purposes, the encapsulation 136 is shown covering a portion of the integrated circuit 102.

Referring now to FIG. 15, therein is shown a top view of the integrated circuit packaging system 100 in the molding phase. The integrated circuit packaging system 100 can include the encapsulation 136 formed covering a number of the integrated circuit 102.

The encapsulation 136 can be formed with the encapsulant or the mold material transferred in a molding direction along a first edge 1502 of the integrated circuit 102. The first edge 1502 is a side at a boundary of the integrated circuit 102. The encapsulation 136 can be formed between the first edge 1502 and another of the first edge 1502 of another of the integrated circuit 102.

The encapsulation 136 can be formed with the encapsulant or the mold material transferred from a second edge 1504 of the integrated circuit 102 to another of the second edge 1504. The second edge 1504 is another side at the boundary of the integrated circuit 102. The second edge 1504 can be shorter than the first edge 1502.

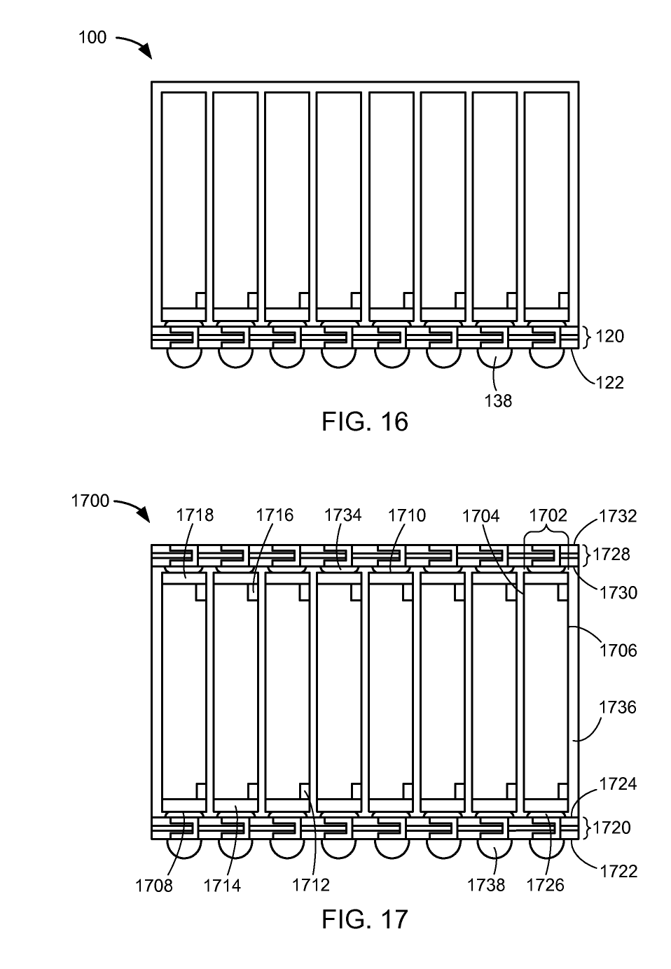

Referring now to FIG. 16, therein is shown the structure of FIG. 14 in an attaching phase. A number of the external connector 138 can be attached to the base bottom side 122. The external connector 138 can be electrically connected to the base substrate 120 and an external system (not shown). For example, the external connector 138 can include a conductive bump.

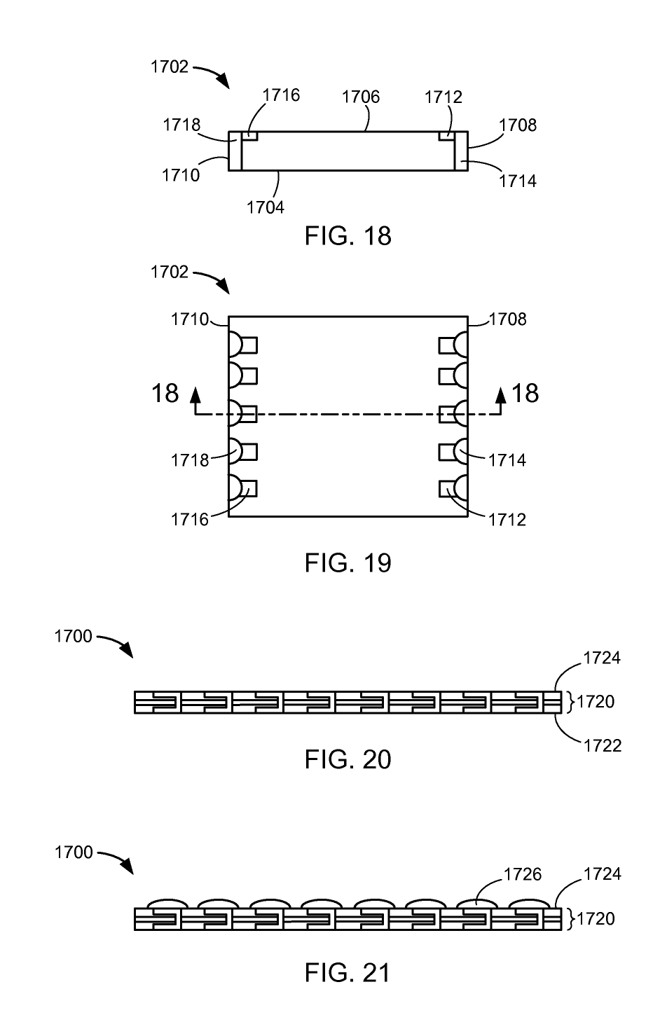

Referring now to FIG. 17, therein is shown a cross-sectional view of an integrated circuit packaging system 1700 in a second embodiment of the present invention. The integrated circuit packaging system 1700 can be formed in a manner similar to the integrated circuit packaging system 100 of FIG. 1, except for the formation of the integrated circuit 102 of FIG. 1 and the encapsulation 136 of FIG. 1, and additions of a connector and a substrate.

The integrated circuit packaging system 1700 can include an integrated circuit 1702. The integrated circuit 1702 can be formed in a manner similar to the integrated circuit 102, except for additions of a terminal and a conductor. The integrated circuit 1702 can include an inactive side 1704, an active side 1706, a first end 1708, a second end 1710, a first terminal 1712, and a first conductor 1714.

The integrated circuit 1702 can include a second terminal 1716, which provides electrical connectivity from or to the integrated circuit 1702. For example, the second terminal 1716 can include a bond pad. The second terminal 1716 can be formed at the active side 1706.

The integrated circuit 1702 can include a second conductor 1718, which is electrically connected to the second terminal 1716. For example, the second conductor 1718 can be formed with an electrically conductive element.

The second conductor 1718 can be formed through the integrated circuit 1702. The second conductor 1718 can be formed at the second end 1710. The second conductor 1718 can be directly on a portion of the second terminal 1716.

A plane of a portion of a side of the second conductor 1718 can be coplanar with a plane of a portion of the inactive side 1704. A plane of a portion of a side of the second conductor 1718 can be coplanar with a plane of a portion of the active side 1706.

The integrated circuit packaging system 1700 can include a base substrate 1720 having a base bottom side 1722 and a base top side 1724. The integrated circuit packaging system 1700 can include a first connector 1726. The base substrate 1720 and the first connector 1726 can be formed in a manner similar to the base substrate 120 of FIG. 1 and the first connector 126 of FIG. 1, respectively.

The integrated circuit packaging system 1700 can include a stack substrate 1728, which is a support structure formed to mount a semiconductor device thereon and electrically connect the semiconductor device thereto. For example, the stack substrate 1728 can include an interposer.

The integrated circuit packaging system 1700 can include the integrated circuit 1702 having double sides, such as the first end 1708 and the second end 1710. The integrated circuit packaging system 1700 can include the base substrate 1720 and the stack substrate 1728 connected to the first end 1708 and the second end 1710, respectively.

The stack substrate 1728 can include a stack bottom side 1730 and a stack top side 1732 opposite the stack bottom side 1730. The stack substrate 1728 can include a number of pads, vertical insertion areas (vias), conductive layers, traces, or a combination thereof to provide electrical connectivity between the stack bottom side 1730 and the stack top side 1732.

The stack substrate 1728 can include the stack top side 1732 to which a further semiconductor package or component can be connected or stacked thereon. For example, the stack substrate 1728 can function as an interposer providing more input/output count.

The integrated circuit 1702 can include the first end 1708 facing the base top side 1724. The integrated circuit 1702 can include the second end 1710 facing away from the base top side 1724 and facing the stack bottom side 1730. The integrated circuit 1702 can be mounted over the base top side 1724.

The integrated circuit packaging system 1700 can include a second connector 1734, which is electrically conductive. The second connector 1734 can be electrically connected to the second conductor 1718 and the stack bottom side 1730. The second connector 1734 can be directly on the second conductor 1718 and the stack bottom side 1730.

The integrated circuit packaging system 1700 can include a number of the integrated circuit 1702 laterally adjacent one another and mounted over the base top side 1724. The integrated circuit packaging system 1700 can include a number of the first connector 1726 connected to a number of the integrated circuit 1702 and the base top side 1724.

The integrated circuit packaging system 1700 can include a number of the second connector 1734 connected to a number of the integrated circuit 1702 and the stack bottom side 1730. The integrated circuit packaging system 1700 can include the integrated circuit 1702 attached to the base substrate 1720 and the stack substrate 1728 with the first connector 1726 and the second connector 1734, respectively, thereby preventing die tilt or displacement.

The integrated circuit packaging system 1700 can include an encapsulation 1736, which covers a semiconductor package to seal a semiconductor device providing mechanical and environmental protection. The encapsulation 1736 can be formed over the base top side 1724 and under the stack bottom side 1730.

The encapsulation 1736 can be formed between the base top side 1724 and under the stack bottom side 1730. The encapsulation 1736 can be formed over the integrated circuit 1702, the first connector 1726, and the second connector 1734.

The integrated circuit packaging system 1700 can include an external connector 1738. The external connector 1738 can be formed in a manner similar to the external connector 138 of FIG. 1.

It has been discovered that the first connector 1726 and the second connector 1734 connect the integrated circuit 1702 to the base substrate 1720 and the stack substrate 1728, respectively, thereby eliminating die tilt or displacement such as die sweep.

It has also been discovered that the second conductor 1718 covers and protects the integrated circuit 1702 at the second end 1710 from the mounting force when mounting a package stacked over the stack substrate 1728 thereby eliminating chip damages.

It has further been discovered that the first connector 1726 connected to the first conductor 1714 and the second connector 1734 connected to the second conductor 1718 significantly reduce misalignment or tilt of the integrated circuit 1702 without further film attachment or wire bonding processes.

Referring now to FIG. 18, therein is shown a cross-sectional view of the integrated circuit 1702 taken along line 18-18 of FIG. 19. The integrated circuit 1702 can include the inactive side 1704, the active side 1706, the first end 1708, and the second end 1710.

The integrated circuit 1702 can include the first terminal 1712 at the active side 1706. The integrated circuit 1702 can include the first conductor 1714 at the first end 1708 and electrically connected to the first terminal 1712.

The integrated circuit 1702 can include the second terminal 1716 at the active side 1706. The integrated circuit 1702 can include the second conductor 1718 at the second end 1710 and electrically connected to the second terminal 1716.

Referring now to FIG. 19, therein is shown a top view of the integrated circuit 1702. The integrated circuit 1702 can include a number of the first terminal 1712 and a number of the first conductor 1714 connected thereto. The integrated circuit 1702 can include a number of the first terminal 1712 and a number of the first conductor 1714 formed in a row or an array adjacent or at the first end 1708.

The integrated circuit 1702 can include a number of the second terminal 1716 and a number of the second conductor 1718 connected thereto. The integrated circuit 1702 can include a number of the second terminal 1716 and a number of the second conductor 1718 formed in a row or an array adjacent or at the second end 1710.

Referring now to FIG. 20, therein is shown a cross-sectional view of the integrated circuit packaging system 1700 in a substrate providing phase of manufacture. The integrated circuit packaging system 1700 can include the base substrate 1720 having the base bottom side 1722 and the base top side 1724.

Referring now to FIG. 21, therein is shown the structure of FIG. 20 in a first deposition phase. The integrated circuit packaging system 1700 can include a number of the first connector 1726 connected to the base top side 1724. The first connector 1726 can be formed directly on the base top side 1724. For example, the first connector 1726 can be deposited on a pad (not shown) of the base substrate 1720.

For example, the first connector 1726 can include a conductive ball, a conductive bump, or a conductive paste. Also for example, the first connector 1726 can be formed with a conductive material including solder, a metal, or a metallic alloy.

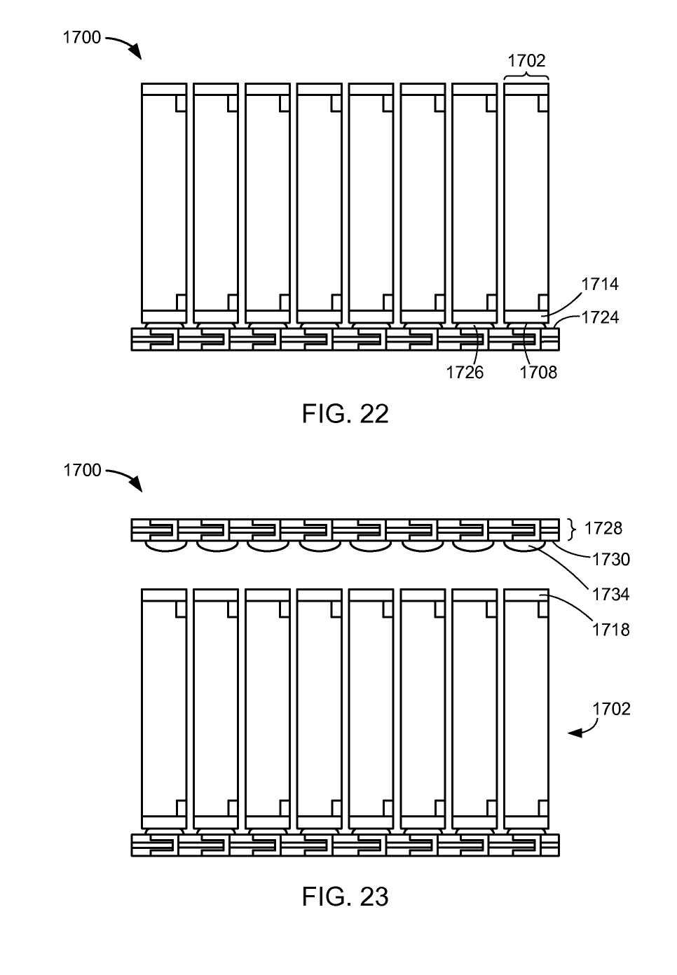

Referring now to FIG. 22, therein is shown the structure of FIG. 21 in a device mounting phase. The integrated circuit 1702 can be mounted over or on the base top side 1724. The integrated circuit 1702 can include the first end 1708 facing the base top side 1724.

The integrated circuit packaging system 1700 can include a number of the integrated circuit 1702 laterally adjacent one another and mounted over the base top side 1724. The integrated circuit packaging system 1700 can include a number of the first connector 1726 connected to a number of the first conductor 1714 and the base top side 1724. The first connector 1726 can be directly on the first conductor 1714 and the base top side 1724.

Referring now to FIG. 23, therein is shown the structure of FIG. 22 in a second deposition phase. The second connector 1734 can be deposited directly on the stack substrate 1728. The second connector 1734 can be connected to the stack bottom side 1730.

For example, the second connector 1734 can include a conductive ball, a conductive bump, or a conductive paste. Also for example, the second connector 1734 can be formed with a conductive material including solder, a metal, or a metallic alloy.

For illustrative purposes, the second connector 1734 is shown connected to the stack bottom side 1730 prior to mounting the stack substrate 1728 over the integrated circuit 1702 in a subsequent phase, although it is understood that the second connector 1734 can be connected in a different manner. For example, the second connector 1734 can be connected to the second conductor 1718 prior to mounting the stack substrate 1728 directly on the second connector 1734.

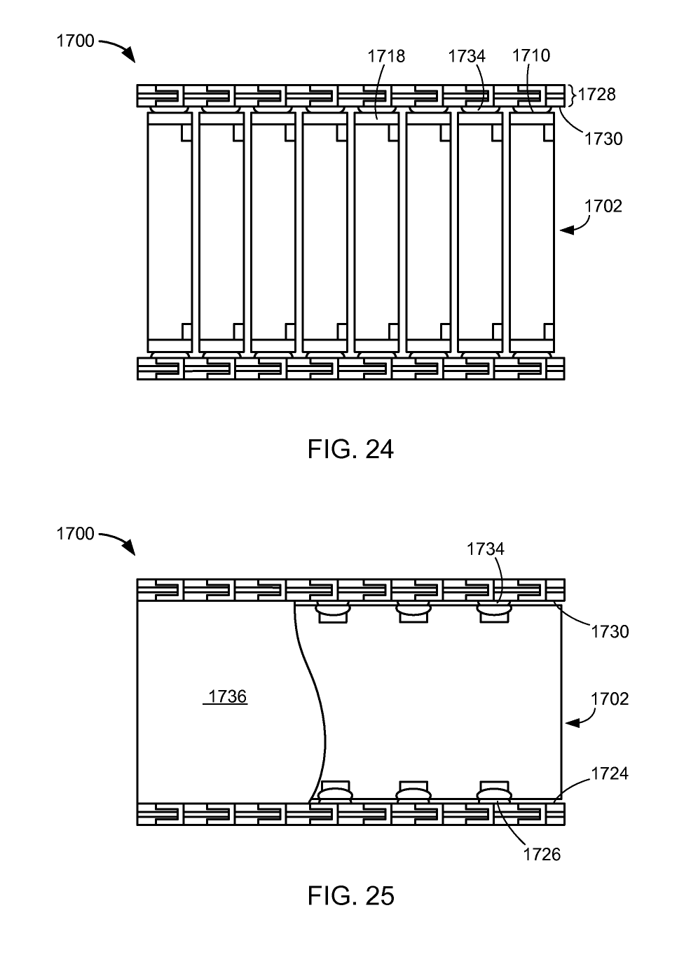

Referring now to FIG. 24, therein is shown the structure of FIG. 23 in a substrate attaching phase. The integrated circuit packaging system 1700 can include the stack substrate 1728 having the stack bottom side 1730 attached on the integrated circuit 1702 with the second connector 1734 directly on the second conductor 1718.

The stack substrate 1728 can be mounted on a number of the integrated circuit 1702. The stack substrate 1728 can be connected to a number of the integrated circuit 1702 with a number of the second connector 1734.

The stack substrate 1728 can be mounted on the integrated circuit 1702 with the stack bottom side 1730 facing the second end 1710. The stack substrate 1728 can be attached to the second end 1710 with the second connector 1734. The stack substrate 1728 can include the stack bottom side 1730 on the second conductor 1718.

Referring now to FIG. 25, therein is shown the structure of FIG. 24 in a molding phase. The integrated circuit packaging system 1700 can include the encapsulation 1736 formed over the base top side 1724 and under the stack bottom side 1730.

The encapsulation 1736 can be formed between the base top side 1724 and under the stack bottom side 1730. The encapsulation 1736 can cover the integrated circuit 1702, the first connector 1726, and the second connector 1734.

For illustrative purposes, the encapsulation 1736 is shown in the process of being formed. Also for illustrative purposes, the encapsulation 1736 is shown covering a portion of the integrated circuit 1702.

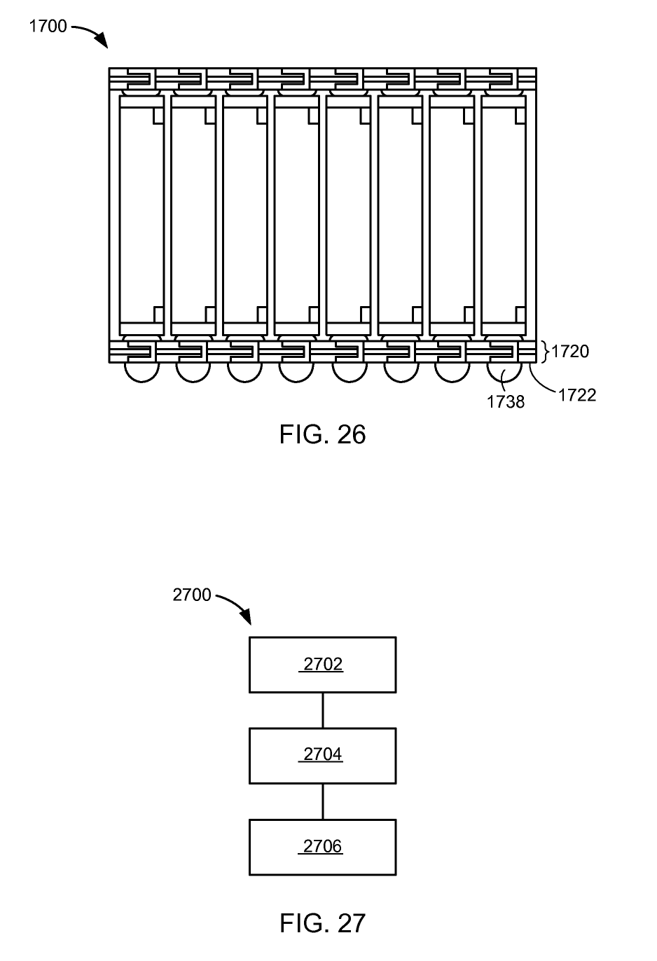

Referring now to FIG. 26, therein is shown the structure of FIG. 25 in a connector attaching phase. A number of the external connector 1738 can be attached to the base bottom side 1722. The external connector 1738 can be electrically connected to the base substrate 1720 and an external system (not shown).

Referring now to FIG. 27, therein is shown a flow chart of a method 2700 of manufacture of the integrated circuit packaging system 100 in a further embodiment of the present invention. The method 2700 includes: providing a base substrate having a base bottom side and a base top side in a block 2702; mounting an integrated circuit perpendicular to the base top side, the integrated circuit having a first conductor partially exposed at a first end facing and connected to the base top side in a block 2704; and forming an encapsulation over the integrated circuit in a block 2706.

Thus, it has been discovered that the integrated circuit packaging system of the present invention furnishes important and heretofore unknown and unavailable solutions, capabilities, and functional aspects for device mount. The resulting method, process, apparatus, device, product, and/or system is straightforward, cost-effective, uncomplicated, highly versatile and effective, can be surprisingly and unobviously implemented by adapting known technologies, and are thus readily suited for efficiently and economically manufacturing integrated circuit packaging systems fully compatible with conventional manufacturing methods or processes and technologies.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
providing a base substrate having a base bottom side and a base top side;
mounting an integrated circuit perpendicular to the base top side, the integrated circuit having a first conductor partially exposed at a first end facing and connected to the base top side; and
forming an encapsulation over the integrated circuit.

2. The method as claimed in claim 1 wherein mounting the integrated circuit includes mounting the integrated circuit having a first terminal and the first conductor directly on a portion of the first terminal.

3. The method as claimed in claim 1 wherein mounting the integrated circuit includes mounting the integrated circuit having an active side and the first conductor at the first end intersecting the active side.

4. The method as claimed in claim 1 wherein mounting the integrated circuit includes mounting integrated circuits perpendicular to the base top side.

5. The method as claimed in claim 1 further comprising mounting a stack substrate on the integrated circuit.

6. A method of manufacture of an integrated circuit packaging system comprising:
providing a base substrate having a base bottom side and a base top side;
forming a first connector directly on the base top side;
mounting an integrated circuit perpendicular to the base top side, the integrated circuit having a first conductor partially exposed at a first end facing and connected to the base top side with the first connector; and
forming an encapsulation over the integrated circuit.

7. The method as claimed in claim 6 wherein mounting the integrated circuit includes mounting the integrated circuit having a first terminal at an active side and the first conductor directly on a portion of the first terminal.

8. The method as claimed in claim 6 wherein mounting the integrated circuit includes mounting the integrated circuit having an inactive side, an active side, and the first conductor at the first end intersecting the inactive side and the active side.

9. The method as claimed in claim 6 wherein mounting the integrated circuit includes mounting integrated circuits perpendicular to the base top side, each of the integrated circuits having the first conductor on the base top side.

10. The method as claimed in claim 6 further comprising:
connecting a second connector to the integrated circuit; and
mounting a stack substrate directly on the second connector.

11. An integrated circuit packaging system comprising:
a base substrate having a base bottom side and a base top side;
an integrated circuit perpendicular to the base top side, the integrated circuit having a first conductor partially exposed at a first end facing and connected to the base top side; and
an encapsulation over the integrated circuit.

12. The system as claimed in claim 11 wherein the integrated circuit includes a first terminal and the first conductor directly on a portion of the first terminal.

13. The system as claimed in claim 11 wherein the integrated circuit includes an active side and the first conductor at the first end intersecting the active side.

14. The system as claimed in claim 11 wherein the integrated circuit includes integrated circuits perpendicular to the base top side.

15. The system as claimed in claim 11 further comprising a stack substrate on the integrated circuit.

16. The system as claimed in claim 11 further comprising:
a first connector directly on the base top side; and
wherein:
the integrated circuit includes the first end connected to the base top side with the first connector.

17. The system as claimed in claim 16 wherein the integrated circuit includes a first terminal at an active side and the first conductor directly on a portion of the first terminal.

18. The system as claimed in claim 16 wherein the integrated circuit includes an inactive side, an active side, and the first conductor at the first end intersecting the inactive side and the active side.

19. The system as claimed in claim 16 wherein the integrated circuit includes integrated circuits perpendicular to the base top side, each of the integrated circuits having the first conductor on the base top side.

20. The system as claimed in claim 16 further comprising:
a second connector connected to the integrated circuit; and
a stack substrate directly on the second connector.
